(19) United States
(12) Patent Application Publication
(10) Pub. No.: US 2026/0039268 A1
(43) Pub. Date: Feb. 5, 2026

(54) FILTER DEVICE AND ANTENNA DEVICE

(71) Applicant: Murata Manufacturing Co., Ltd., Nagaokakyo-shi (JP)

(72) Inventor: Shinya TACHIBANA, Nagaokakyo-shi (JP)

(73) Assignee: Murata Manufacturing Co., Ltd., Nagaokakyo-shi (JP)

(21) Appl. No.: 19/351,353

(22) Filed: Oct. 7, 2025

Related U.S. Application Data
(63) Continuation of application No. PCT/JP2024/002365, filed on Jan. 26, 2024.

(30) Foreign Application Priority Data
Apr. 28, 2023 (JP) 2023-074456

(51) Int. Cl. H03H 7/01; H03H 1/00; H03H 7/09

(52) U.S. Cl. CPC H03H 7/175; H03H 7/09; H03H 2001/0085

(57) ABSTRACT

The present disclosure provides a filter device with which good characteristics can be obtained even when an attenuation band due to parallel resonance and a passband due to series resonance are close to each other. The filter device according to the present disclosure includes a first terminal, a second terminal, and a first inductor. A first path and a second path are provided in parallel with each other between the first inductor and the second terminal. A series resonator is in the first path and includes a second inductor, a capacitor connected in series with the second inductor, and a third inductor connected in series with the second inductor and the capacitor. Magnetic coupling between the first inductor and the third inductor is weaker than magnetic coupling between the first inductor and the second inductor.

### CROSS-REFERENCE TO RELATED APPLICATIONS

The present application is bypass continuation of International Application PCT/JP2024/002365, filed Jan. 26, 2024, which claims priority to Japanese patent application JP 2023-074456, filed Apr. 28, 2023, the entire contents of each of which being incorporated herein by reference.

### TECHNICAL FIELD

The present disclosure relates to a filter device and an antenna device.

### BACKGROUND ART

Filter devices such as a band eliminate filter and a band pass filter are provided in a radio-frequency circuit. As an example of such a filter device provided in the radio-frequency circuit, a filter device is disclosed in Japanese Patent No. 6531824 (Patent Document 1). This filter device includes a first inductor and a first capacitor included in a first series circuit and a second inductor connected in parallel with the first series circuit.

### CITATION LIST

### Patent Document

Patent Document 1: Japanese Patent No. 6531824

### SUMMARY

### Technical Problems

However, with the filter device disclosed in Japanese Patent No. 6531824 (Patent Document 1), when an attenuation band (attenuation pole) due to parallel resonance and a passband due to series resonance are close to each other, it is difficult to maintain both the attenuation characteristic and the bandpass characteristic at high levels.

The present disclosure has been made to address such a problem and is aimed at providing a filter device with which good characteristics can be obtained even when an attenuation band due to parallel resonance and a passband due to series resonance are close to each other.

### Solutions to Problems

A filter device according to the present disclosure has an attenuation band. The filter device includes a first terminal, a second terminal, a first inductor connected to the first terminal, and a series resonator disposed in a first path out of the first path and a second path provided in parallel with each other between the first inductor and the second terminal. The series resonator includes a second inductor, a capacitor connected in series with the second inductor, and a third inductor connected in series with the second inductor and the capacitor. Magnetic coupling between the first inductor and the third inductor is weaker than magnetic coupling between the first inductor and the second inductor.

An antenna device according to the present disclosure is configured to be able to radiate a radio wave. The antenna device includes a radiating element, a feeding circuit configured to feed a radio-frequency signal to the radiating element, and the above-described filter device provided between an antenna and the feeding circuit.

### Advantageous Effects

In the filter device according to the present disclosure, the series resonator is disposed in the first path, and the first inductor and the second inductor are magnetically coupled to each other. Thus, a high attenuation characteristic and bandpass characteristic can be obtained even when the attenuation band due to the parallel resonance and the passband due to the series resonance are close to each other.

### BRIEF DESCRIPTION OF DRAWINGS

FIG. 1 is a perspective view of a filter device according to Embodiment 1.

FIG. 2 includes circuit diagrams of the filter device and an antenna device according to Embodiment 1.

FIG. 3 illustrates an attenuation characteristic of the filter device.

FIG. 4 is an exploded plan view illustrating the configuration of the filter device according to Embodiment 1.

FIG. 5 is a perspective view of a filter device according to Embodiment 2.

FIG. 6 is an exploded plan view illustrating the configuration of the filter device according to Embodiment 2.

FIG. 7 is a graph illustrating the attenuation characteristic of the filter device according to Embodiment 2.

FIG. 8 is a perspective view of a filter device according to Embodiment 3.

FIG. 9 is an exploded plan view illustrating the configuration of the filter device according to Embodiment 3.

FIG. 10 is a graph illustrating the attenuation characteristic of the filter device according to Embodiment 3.

FIG. 11 includes circuit diagrams of an antenna device according to Modification 1.

FIG. 12 includes circuit diagrams of an antenna device according to Modification 2.

FIG. 13 includes circuit diagrams of an antenna device according to Modification 3.

### DESCRIPTION OF EMBODIMENTS

Hereinafter, a filter device according to embodiments will be described in detail with reference to the drawings. The same or corresponding parts are denoted by the same reference numerals in the drawings, and the description of the same or corresponding parts is not repeated.

### Embodiment 1

### [Structure of Filter Device]

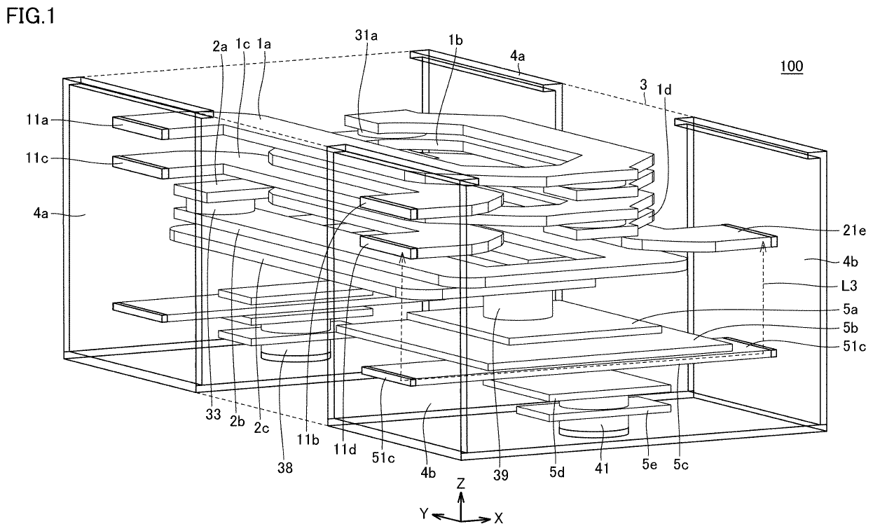

First, a filter device according to Embodiment 1 is described with reference to the drawings. FIG. 1 is a perspective view of a filter device 100 according to Embodiment 1. Here, in FIG. 1, the short edge direction of the filter device 100 is defined as the X direction, the long edge direction of the filter device 100 is defined as the Y direction, and the height direction of the filter device 100 is defined as the Z direction.

The filter device 100 is a rectangular parallelepiped-shaped chip component in which two inductors and a single capacitor are laminated in the Z direction. The filter device 100 includes an insulating body 3 formed by laminating a plurality of insulating substrates (insulating body layers) on which first conductor patterns of a first inductor L1, second conductor patterns of a second inductor L2, and electrode patterns of a capacitor C1 are formed as illustrated in FIG. 1. The laminating direction of the insulating substrates is the Z direction, and the arrow direction indicates an upper layer direction. The insulating substrates are formed of a material such as, for example, an insulating material mainly including borosilicate glass or insulating resin such as alumina, zirconia, or polyimide resin. In the insulating body 3, interfaces between the plurality of insulating substrates are not necessarily clarified due to processing such as firing and solidification.

Outer electrodes 4a (first outer electrodes) and outer electrodes 4b (second outer electrodes) as illustrated in FIG. 1 are formed at two positions in the Y direction in the insulating body 3 of the filter device 100. The insulating body 3 has a pair of main surfaces that face each other. The lower main surface illustrated in FIG. 1 is a mounting surface that faces a circuit board. According to Embodiment 1, the lower main surface illustrated in FIG. 1 is referred to as a bottom surface, and the upper main surface illustrated in FIG. 1 is referred to as a top surface.

Electrode patterns of the outer electrodes 4a and the outer electrodes 4b are formed not only on the bottom surface of the insulating body 3 but also on the side surfaces connecting the main surfaces of the insulating body 3. When the insulating body 3 is seen from the side surface on the short edge side (XZ surface), the outer electrodes 4a and the outer electrodes 4b form a U shape. Thus, the outer electrodes 4a provided on the respective side surfaces (a first side surface and a second side surface) of the insulating body 3 facing each other are at the same potential due to the electrode pattern provided on the bottom surface of the insulating body 3. Likewise, the outer electrodes 4b provided on the respective side surfaces of the insulating body 3 facing each other are at the same potential due to the electrode pattern provided on the bottom surface of the insulating body 3.

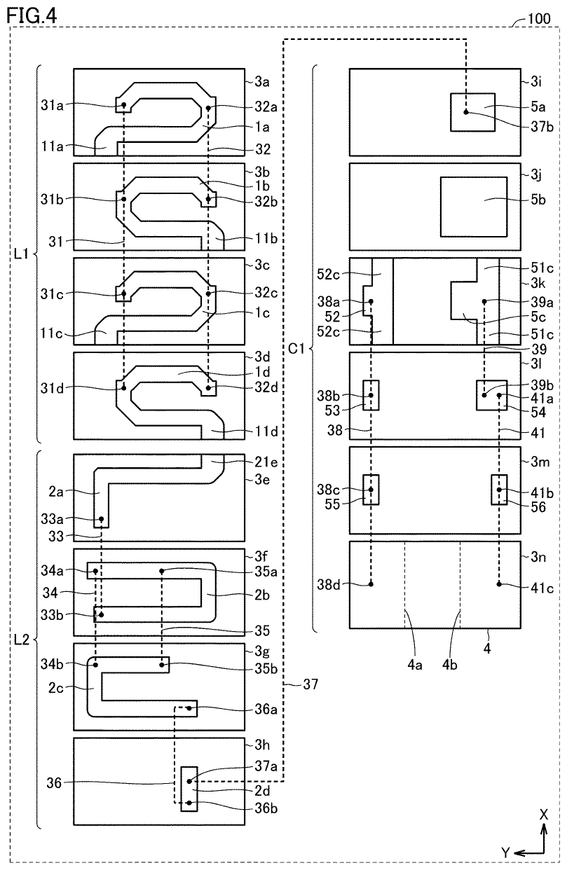

A first conductor pattern 1a (first conductor pattern) of the first inductor L1 and the outer electrode 4a are electrically connected to each other via a wiring pattern 11a at the side surface of the insulating body 3. An electrode pattern 5b (second electrode pattern) of the capacitor C1 and the outer electrode 4b are electrically connected to each other via wiring patterns 51a (see FIG. 4) and 51b at the side surface of the insulating body 3.

In the first inductor L1, a plurality of first conductor patterns 1a to 1d are laminated such that the first conductor patterns 1a to 1d are in parallel to the main surface of the insulating body 3, and the first conductor patterns 1a to 1d are electrically connected via via conductors 31 and 32. The first conductor patterns 1a and 1c and the outer electrode 4a are electrically connected to each other via the wiring patterns 11a and 11c at the side surface (first side surface) of the insulating body 3. First conductor patterns 1b and 1d and the outer electrode 4b are electrically connected to each other via wiring patterns 11b and 11d at the side surface (second side surface) of the insulating body 3.

In the second inductor L2, a plurality of second conductor patterns 2a to 2d are laminated such that the second conductor patterns 2a to 2d are in parallel to the main surface of the insulating body 3, and the second conductor patterns 2a to 2d are electrically connected via via conductors 33 to 36. The second conductor pattern 2a and the outer electrode 4b are electrically connected to each other via a wiring pattern 21e at the side surface (second side surface) of the insulating body 3.

The capacitor C1 is formed by laminating a plurality of electrode patterns 5a to 5c below the second inductor L2 with insulating layers interposed therebetween. Regarding the capacitor C1, the second conductor pattern 2d (see FIG. 4) of the second inductor L2 and the electrode pattern 5a are electrically connected to each other via a via conductor 39. The electrode pattern 5b is a floating electrode that is not electrically connected to the outer electrode 4b, other wiring patterns, or the like. The electrode pattern 5c is electrically connected to the outer electrodes 4b via a wiring pattern 51c at both side surfaces (the first side surface and the second side surface) of the insulating body 3 facing each other. Furthermore, the electrode pattern 5c is electrically connected to the outer electrode 4b via a via conductor 41.

Furthermore, in the filter device 100, a third inductor L3 includes a path extending from the wiring patterns 11b and 11d provided at a first end of the first inductor L1 through the outer electrode 4b on the side surface (first side surface) of the insulating body 3, the electrode pattern 5c of the capacitor C1, and the outer electrode 4b on the side surface (second side surface) of the insulating body 3, to the wiring pattern 21e provided at a first end of the second inductor L2. Opening surfaces of the first inductor L1 and the second inductor L2 forming coils are formed so as to be parallel to the XY plane, and the openings are superposed on each other when seen in plan view seen from the top surface side. Thus, a strong magnetic coupling is exerted on the first inductor L1 and the second inductor L2. Meanwhile, an opening surface of the third inductor L3 forming a coil is formed in the XZ plane. Thus, the first inductor L1 and the third inductor L3 are not magnetically coupled, or the magnetic coupling between the first inductor L1 and the third inductor L3 is weaker than the magnetic coupling between the first inductor L1 and the second inductor L2. In other words, this orthogonal orientation of the coil opening surfaces for the first inductor L1 (XY plane) and the third inductor L3 (XZ plane) results in a substantially weaker magnetic coupling between them.

The second inductor L2, the third inductor L3, and the capacitor C1 are connected in series in the insulating body 3 and included in an LC series resonator. Accordingly, the filter device 100 produces an attenuation pole by using the LC series resonator and has a resonant frequency. Next, a circuit configuration of the filter device 100 and an antenna device using the filter device 100 are described in detail.

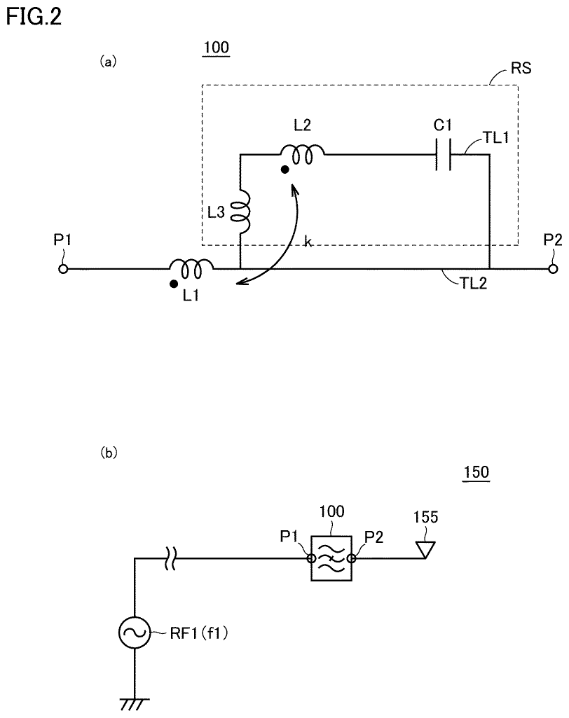

FIG. 2 includes circuit diagrams of the filter device and the antenna device according to Embodiment 1. In FIG. 2, (a) is a circuit diagram of the filter device 100 according to Embodiment 1 and (b) is a circuit diagram of an antenna device 150 according to Embodiment 1. The filter device 100 is a trap filter that is used for the antenna device 150, blocks the passage of radio-frequency signals of a specific frequency band, and attenuates the radio-frequency signals of a specific frequency band. The filter device 100 is also referred to as a band eliminate filter.

The antenna device 150 includes a feeding circuit RF1, the filter device 100, and a radiating element 155. The antenna device 150 is mounted on, for example, a mobile terminal such as a cellular phone, a smartphone, or a tablet, or a communication device such as a personal computer with a communication function.

The feeding circuit RF1 is configured to feed radio-frequency signals in a frequency band of the f1 band to the radiating element 155. The radiating element 155 is, for example, a monopole antenna and able to radiate the radio-frequency signals of the f1 band fed from the feeding circuit RF1 into the air as radio waves.

When the antenna device 150 is used near an antenna of, for example, the f0 band (#f1 band), the filter device 100 that attenuates the radio-frequency signals of the frequency band of the f0 band and allows the radio-frequency signals of the frequency band of the f1 band to pass therethrough is useful. In the filter device 100, an attenuation band (attenuation pole) due to parallel resonance is the frequency band of the f0 band, and a passband due to series resonance is the frequency band of the f1 band.

Specifically, as illustrated in (a) of FIG. 2, the filter device 100 includes a terminal P1 and a terminal P2. The terminal P1 is provided for connecting the filter device 100 to a transmission line on the feeding circuit RF1 side. The terminal P2 is provided for connecting the filter device 100 to a transmission line on the radiating element 155 side. The terminal P1 (first terminal) corresponds to the outer electrodes 4a illustrated in FIG. 1. The terminal P2 (second terminal) corresponds to the outer electrodes 4b illustrated in FIG. 1.

When the feeding circuit RF1 feeds the radio-frequency signals to the radiating element 155 via the filter device 100, the terminal P1 serves as an input terminal and the terminal P2 serves as an output terminal. When the radio-frequency signals received by the radiating element 155 are transferred to a circuit on the feeding circuit RF1 side via the filter device 100, the terminal P1 serves as an output terminal and the terminal P2 serves as an input terminal.

As illustrated in (a) of FIG. 2, the filter device 100 includes the first inductor L1, the second inductor L2, the third inductor L3, and the capacitor C1. A first path TL1 and a second path TL2 are provided between the first inductor L1 and the terminal P2. An LC series resonator RS in which the third inductor L3, the second inductor L2, and the capacitor C1 are connected in series is provided on the first path TL1. The second path TL2 is a short path.

While the first inductor L1 and the second inductor L2 are magnetically coupled to each other, the magnetic coupling between the first inductor L1 and the third inductor L3 is weaker than the magnetic coupling between the first inductor L1 and the second inductor L2, and may approach zero depending on the physical layout. Thus, although a mutual inductance M is generated between the first inductor L1 and the second inductor L2, the mutual inductance M is not generated between the first inductor L1 and the third inductor L3. A parallel resonator is formed when the inductances are generated respectively in the first path TL1 and the second path TL2 due to the mutual inductance M generated between the first inductor L1 and the second inductor L2. The magnetic coupling between the first inductor L1 and the third inductor L3 may not be completely blocked, as along as the magnetic coupling therebetween is weaker than the magnetic coupling between the first inductor L1 and the second inductor L2.

When, as in the filter device 100, the LC series resonator RS is provided on the first path TL1 and the parallel resonator includes the first path TL1 and the second path TL2, the resonant frequency of the parallel resonator is coincident with the serial resonant frequency f0 of the LC series resonator RS and becomes the parallel resonant frequency of the attenuation band (f0 band) of the filter device 100. The serial resonant frequency f0 of the LC series resonator RS is determined by the inductances of the inductors (the second inductor L2 and the third inductor L3) included in the LC series resonator RS and the capacitance of the capacitor (capacitor C1). Thus, when, for example, the attenuation band (f0 band) of the filter device 100 is to be adjusted to the low frequency side, the inductor included in the LC series resonator RS may be increased.

However, when the inductance of the second inductor L2 magnetically coupled to the first inductor L1 is increased, in the structure of the filter device 100 illustrated in FIG. 1, a layer on which a second conductive pattern being part of the second inductor L2 is formed may be added. When the layer on which the second conductive pattern is formed is added without changing the size of the filter device 100, the distance between the first inductor L1 and the second inductor L2 reduces, and a coupling coefficient k unintentionally increases. In the filter device 100, reduction of the coupling coefficient k allows the serial resonant frequency (center frequency) to become closer to the parallel resonant frequency (center frequency). However, conversely, when the coupling coefficient k increases, the width of the attenuation pole increases. Thus, when the coupling coefficient k increases, it is difficult to realize a small-sized steep filter device having the attenuation pole in a low frequency band.

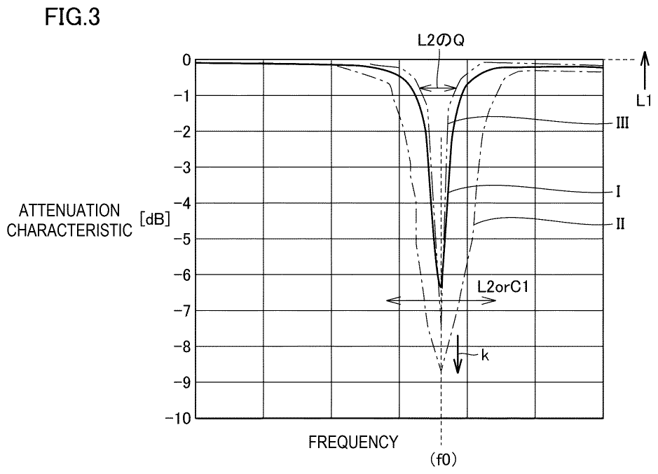

Here, relationships between parameters of the first inductor L1 and the second inductor L2 of the filter device and an attenuation characteristic of the filter device are described. FIG. 3 illustrates an attenuation characteristic of the filter device. Referring to FIG. 3, the horizontal axis represents the frequency and the vertical axis represents an attenuation characteristic. The attenuation increases downward in FIG. 3. FIG. 3 illustrates the attenuation characteristic of the filter device having the attenuation pole of a certain resonant frequency f0. The frequency of the resonant frequency f0 can be adjusted by changing the inductance of the second inductor L2 or the capacitance of the capacitor C1. That is, when the resonant frequency f0 is wanted to be adjusted to the low frequency side, the second inductor L2 is increased or the capacitance of the capacitor C1 is increased. When the capacitance of the capacitor C1 is increased without changing the size of the filter device, a region where the opening portions of the first and the second inductors L1 and L2 and the electrode of the capacitor C1 are superposed on each other in plan view seen from the top surface side may increase and block the magnetic flux.

Furthermore, when the coupling coefficient k increases, the value of the attenuation pole of the resonant frequency f0 reduces (the depth of the attenuation pole increases), and accordingly, the width of the attenuation pole increases. Specifically, graph I represents the attenuation characteristic of the filter device when the coupling coefficient k is a certain value. When the coupling coefficient k increases, the attenuation characteristic of the filter device changes to graph II and the width of the attenuation pole increases.

The width of the attenuation pole also changes depending on the quality factor of the second inductor L2. Specifically, graph I represents the attenuation characteristic of the filter device when the quality factor of the second inductor L2 is a certain value. When the quality factor of the second inductor L2 increases, the attenuation characteristic of the filter device changes to graph III and the width of the attenuation pole reduces. Meanwhile, the inductance of the first inductor L1 influences the bandpass characteristic at every frequency. In particular, when the inductance of the first inductor L1 reduces, a passage loss improves on the high bandwidth side of the resonant frequency f0 in a direction indicated by an arrow illustrated in FIG. 3.

In consideration of the above-described relationships, in the filter device 100, the third inductor L3 not magnetically couple to the first inductor L1 is provided other than the second inductor L2. In this way, the inductance of the inductors included in the LC series resonator RS can be increased. Thus, the filter device 100 allows the reduction of the resonant frequency f0 without changing the coupling coefficient k between the first inductor L1 and the second inductor L2, and the steep filter device having the attenuation pole in the low frequency band can be realized.

### [Exploded Plan View of Filter Device]

Next, the configuration of each layer is described with reference to an exploded plan view. FIG. 4 is an exploded plan view illustrating the configuration of the filter device 100 according to Embodiment 1. First, as illustrated in FIG. 4, the first conductor patterns 1a to 1d, the second conductor patterns 2a to 2d, the wiring patterns 11a to 11b, 21e, 51c, 52c, and 52 to 56, and the electrode patterns 5a to 5c are formed on insulating substrates 3a to 3n by a printing method.

The first conductor pattern 1a being part of the first inductor L1 is formed on the insulating substrate 3a. The first conductor pattern 1a is a hexagonal pattern of about a single counterclockwise loop from the lower left side of the insulating substrate 3a in the pages of FIG. 4. The beginning of the first conductor pattern 1a is electrically connected to the outer electrode 4a (see FIG. 1) via the wiring patterns 11a. A connection portion 31a connected to the via conductor 31 is provided near the termination of the first conductor pattern 1a. A connection portion 32a connected to the via conductor 32 is provided at a midpoint of the first conductor pattern 1a.

A first conductor pattern 1b being part of the first inductor L1 is formed on the insulating substrate 3b. The first conductor pattern 1b is a hexagonal pattern of about a single clockwise loop from the lower right side of the insulating substrate 3b in the pages of FIG. 4. The beginning of the first conductor pattern 1b is electrically connected to the outer electrode 4b (see FIG. 1) via the wiring patterns 11b. A connection portion 31b connected to the via conductor 31 is provided near the termination of the first conductor pattern 1b. A connection portion 32b connected to the via conductor 32 is provided at a midpoint of the first conductor pattern 1b.

The first conductor pattern 1c being part of the first inductor L1 is formed on the insulating substrate 3c. The first conductor pattern 1c has the same shape as the shape of the first conductor pattern 1a and is a hexagonal pattern of about a single counterclockwise loop from the lower left side of the insulating substrate 3c in the pages of FIG. 4. The beginning of the first conductor pattern 1c is electrically connected to the outer electrode 4a (see FIG. 1) via the wiring patterns 11c. A connection portion 31c connected to the via conductor 31 is provided near the termination of the first conductor pattern 1c. A connection portion 32c connected to the via conductor 32 is provided at a midpoint of the first conductor pattern 1c.

The first conductor pattern 1d being part of the first inductor L1 is formed on the insulating substrate 3d. The first conductor pattern 1d has the same shape as the shape of the first conductor pattern 1b and is a hexagonal pattern of about a single clockwise loop from the lower right side of the insulating substrate 3d in the pages of FIG. 4. The beginning of the first conductor pattern 1d is electrically connected to the outer electrode 4b (see FIG. 1) via the wiring patterns 11d. A connection portion 31d connected to the via conductor 31 is provided near the termination of the first conductor pattern 1d. A connection portion 32d connected to the via conductor 32 is provided at a midpoint of the first conductor pattern 1d.

In the first inductor L1, two coils of about a single turn are connected in parallel as follows: the first conductor patterns 1a and 1c are connected in parallel and the first conductor patterns 1b and 1d are connected in parallel; and the first conductor patterns 1a and 1c having been connected in parallel and the first conductor patterns 1b and 1d having been connected in parallel are connected in series.

The second conductor pattern 2a being part of the second inductor L2 is formed on the insulating substrate 3e. The second conductor pattern 2a is an L-shaped pattern of about a half of a counterclockwise loop from the upper right side of the insulating substrate 3e in the pages of FIG. 4. The beginning of the second conductor pattern 2a is electrically connected to the outer electrode 4b (see FIG. 1) via the wiring pattern 21e. A connection portion 33a connected to the via conductor 33 is provided near the termination of the second conductor pattern 2a.

The second conductor pattern 2b being part of the second inductor L2 is formed on the insulating substrate 3f. The second conductor pattern 2b is a U-shaped pattern of about a three-quarter counterclockwise loop from the lower left side of the insulating substrate 3f in the pages of FIG. 4. A connection portion 33b connected to the via conductor 33 is provided near the beginning of the second conductor pattern 2b. A connection portion 34a connected to the via conductor 34 is provided near the termination of the second conductor pattern 2b. A connection portion 35a connected to the via conductor 35 is provided at a midpoint of the second conductor pattern 2b.

The second conductor pattern 2c being part of the second inductor L2 is formed on the insulating substrate 3g. The second conductor pattern 2c is a U-shaped pattern of about a three-quarter counterclockwise loop from near or from the upper center of the insulating substrate 3g in the pages of FIG. 4. A connection portion 35b connected to the via conductor 35 is provided near the beginning of the second conductor pattern 2c. A connection portion 36a connected to the via conductor 36 is provided near the termination of the second conductor pattern 2c. A connection portion 34b connected to the via conductor 34 is provided at a midpoint of the second conductor pattern 2c.

The second conductor pattern 2d being part of the second inductor L2 is formed on the insulating substrate 3h. The second conductor pattern 2d is an I-shaped pattern formed so as to extend from the lower right side to the upper side of the insulating substrate 3h in the pages of FIG. 4. A connection portion 36b connected to the via conductor 36 is provided near the beginning of the second conductor pattern 2d. A connection portion 37a connected to a via conductor 37 is provided near the termination of the second conductor pattern 2d.

The second inductor L2 is included in an about two-turn coil in which the second conductor patterns 2a to 2d are connected in series. In plan view seen from the top surface side, the opening portion of the second inductor L2 has a rectangular shape while the opening portion of the first inductor L1 has a hexagonal shape. When the opening portion of the second inductor L2 has a rectangular shape, the inductance of the second inductor L2 can be increased by effectively utilizing a space inside the insulating body 3. When the opening portion of the first inductor L1 has a hexagonal shape, in plan view seen from the top surface side, the area by which the opening portions of the first inductor L1 and the second inductor L2 are superposed on each other can be changed, and accordingly, the coupling coefficient k can be adjusted. When the opening portion of the first inductor L1 has a hexagonal shape, the inductance of the first inductor L1 can be reduced, and accordingly, the bandpass characteristic of the filter device 100 can be improved. The shape of the opening portion of the first inductor L1 is not limited to the hexagonal shape. It is sufficient that the opening portion of the first inductor L1 have a shape other than a rectangular shape. The opening portion of the first inductor L1 may have a polygonal shape such as an octagonal shape.

The electrode pattern 5a (first electrode pattern) included in one of the electrodes of the capacitor C1 is formed on the insulating substrate 3i. In plan view seen from the top surface side, the electrode pattern 5a is provided at a position on the right side of the insulating body 3. That is, the electrode pattern 5a is provided at a position so as to avoid superposition on the opening portion of the first inductor L1 and the opening portion of the second inductor L2 as much as possible. In other words, the capacitor does not substantially overlap with an opening of the first inductor or an opening of the second inductor.

The electrode pattern 5a includes a connection portion 37b connected to the via conductor 37.

The electrode pattern 5b is formed on the insulating substrate 3j. In plan view seen from the top surface side, the electrode pattern 5b is provided at a position superposed on the electrode pattern 5a. The electrode pattern 5b is the floating electrode of the capacitor C1 that is not electrically connected to the outer electrode 4b (see FIG. 1).

The electrode pattern 5c included in another electrode of the capacitor C1 is formed on the insulating substrate 3k. In plan view seen from the top surface side, the electrode pattern 5c is provided at a position facing the electrode pattern 5b. The electrode pattern 5c is electrically connected to the outer electrodes 4b (see FIG. 1) at both the side surfaces facing with the wiring patterns 51c interposed therebetween. The electrode pattern 5c includes a connection portion 39a connected to the via conductor 39. Furthermore, in plan view seen from the top surface side, in the insulating substrate 3k, the wiring pattern 52 is provided at a position on the left side of the insulating body 3. The wiring pattern 52 is electrically connected to the outer electrodes 4a (see FIG. 1) on both the side surfaces facing each other with the wiring patterns 52c interposed therebetween. The wiring pattern 52 includes a connection portion 38a connected to a via conductor 38.

In the capacitor C1, the electrode pattern 5a, the electrode pattern 5b, and the electrode pattern 5c are included in a capacitor. The insulating substrates 31 to 3n are further provided in a lower layer of the capacitor C1. The insulating substrate 31 includes the wiring pattern 53 including a connection portion 38b connected to the via conductor 38 and the wiring pattern 54 including a connection portion 39b connected to the via conductor 39 and a connection portion 41a connected to the via conductor 41. The insulating substrate 3m includes the wiring pattern 55 including a connection portion 38c connected to the via conductor 38 and the wiring pattern 56 including a connection portion 41b connected to the via conductor 41. The insulating substrate 3n includes a connection portion 38d connected to the via conductor 38 and the wiring pattern 56 including a connection portion 41c connected to the via conductor 41. The via conductor 38 is electrically connected to the outer electrode 4a provided on the bottom surface via the connection portion 38d. The via conductor 41 is electrically connected to the outer electrode 4b provided on the bottom surface via the connection portion 41c.

### Embodiment 2

The following description has been made for the filter device 100 according to Embodiment 1: the third inductor L3 includes the path extending from the wiring patterns 11b and 11d provided at a first end of the first inductor L1 through the outer electrode 4b on the side surface (first side surface) of the insulating body 3, the electrode pattern 5c of the capacitor C1, and the outer electrode 4b on the side surface (second side surface) of the insulating body 3, to the wiring pattern 21e provided at a first end of the second inductor L2. In Embodiment 2, the configuration of a filter device to which a smaller inductance than the inductance of the third inductor L3 according to Embodiment 1 is added is described.

### [Structure of Filter Device]

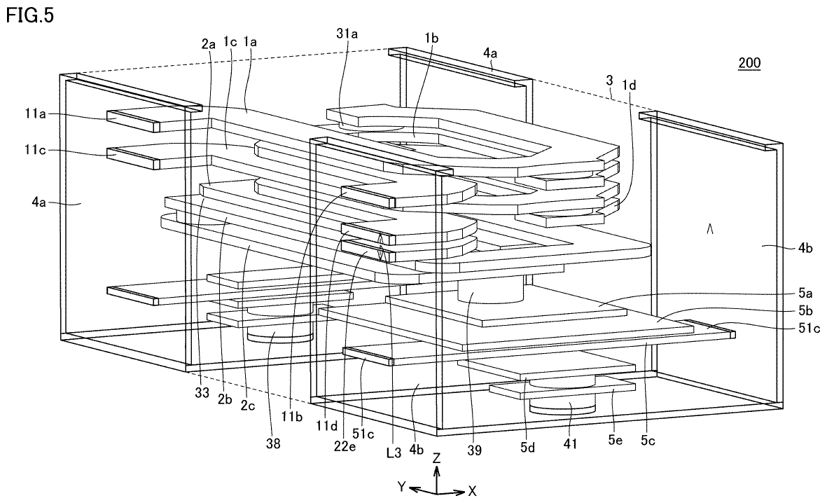

First, a filter device according to Embodiment 2 is described with reference to the drawings. FIG. 5 is a perspective view of a filter device 200 according to Embodiment 2. Here, in FIG. 5, the short edge direction of the filter device 200 is defined as the X direction, the long edge direction of the filter device 200 is defined as the Y direction, and the height direction of the filter device 200 is defined as the Z direction. In the filter device 200 illustrated in FIG. 5, the same elements as those of the filter device 100 illustrated in FIG. 1 are denoted by the same reference numerals, thereby to avoid repetition of the detailed description.

The filter device 200 is a rectangular parallelepiped-shaped chip component in which two inductors and a single capacitor are laminated in the Z direction. The filter device 200 includes the insulating body 3 formed by laminating a plurality of insulating substrates (insulating body layers) on which the first conductor patterns of the first inductor L1, the second conductor patterns of the second inductor L2, and the electrode patterns of the capacitor C1 are formed as illustrated in FIG. 5. Although the configurations of the first inductor L1 and the capacitor C1 of the filter device 200 are the same as those of the filter device 100 illustrated in FIG. 1, the configuration of the second inductor L2 of the filter device 200 is different from that of the filter device 100.

In the second inductor L2, the plurality of second conductor patterns 2a to 2d are laminated such that the second conductor patterns 2a to 2d are in parallel to the main surface of the insulating body 3, and the second conductor patterns 2a to 2d are electrically connected via the via conductors 33 to 36. The second conductor pattern 2a and the outer electrode 4b are electrically connected to each other via a wiring pattern 22e at the side surface (first side surface) of the insulating body 3. The second conductor pattern 2a and the outer electrode 4a are not electrically connected to each other.

Thus, in the filter device 200, the third inductor L3 includes a path extending from the wiring patterns 11b and 11d provided at the first end of the first inductor L1 through the outer electrode 4b on the side surface (first side surface) of the insulating body 3, to the wiring pattern 22e provided at a first end of the second inductor L2. In the third inductor L3, an inductor is formed only by the outer electrode 4b provided on one of the side surfaces of the insulating body 3. Accordingly, the inductance reduces compared to the case where the inductor is formed by outer electrodes 4b provided on both of the side surfaces of the insulating body 3 illustrated in FIG. 1. The opening surface of the third inductor L3 illustrated in FIG. 5 is formed in the XZ plane. Thus, the magnetic coupling between the first inductor L1 and the third inductor L3 is weaker than the magnetic coupling between the first inductor L1 and the second inductor L2.

The second inductor L2, the third inductor L3, and the capacitor C1 are connected in series in the insulating body 3 and included in an LC series resonator. Accordingly, the filter device 200 produces an attenuation pole by using the LC series resonator and has a resonant frequency.

### [Exploded Plan View of Filter Device]

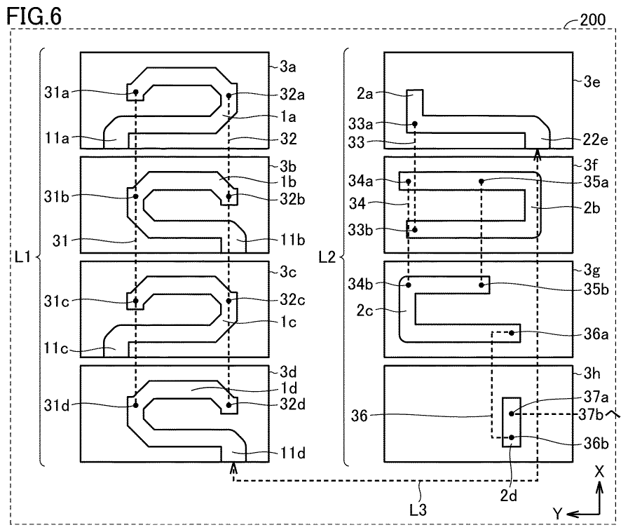

Next, the configuration of each layer is described with reference to an exploded plan view. FIG. 6 is an exploded plan view illustrating the configuration of the filter device 200 according to Embodiment 2. Referring to FIG. 6, the configuration of the filter device 200 is the same as the configuration of the filter device 100 illustrated in FIG. 1 except for that the configuration of the second inductor L2 is different from that of the filter device 100. Thus, exploded plan view of the capacitor C1 is omitted from FIG. 6, and the same elements as those of the filter device 100 are denoted by the same reference numerals, thereby to avoid repetition of the detailed description.

The second conductor pattern 2a being part of the second inductor L2 is formed on the insulating substrate 3e. The second conductor pattern 2a is an L-shaped pattern of about a half of a clockwise loop from the lower right side of the insulating substrate 3e in the pages of FIG. 6. The beginning of the second conductor pattern 2a is electrically connected to the outer electrode 4b (see FIG. 5) via the wiring pattern 22e. The connection portion 33a connected to the via conductor 33 is provided at a midpoint of the termination of the second conductor pattern 2a. The directions of the current flowing through the second conductor pattern 2a and the second conductor pattern 2b are opposite to each other, and the inductance value of the second inductor L2 reduces. Alternatively, instead of the L shape, the second conductor pattern 2a can extend in the upper side of the page of FIG. 6 and can be connected to the wiring pattern 22e from the left side. In this case, the directions of the current flowing through the second conductor pattern 2a and the second conductor pattern 2b are the same, and the inductance value of the second inductor L2 increases compared to that of the pattern illustrated in FIG. 5. Thus, the inductance value may be adjusted by adding a pattern in the opposite direction to a connection position.

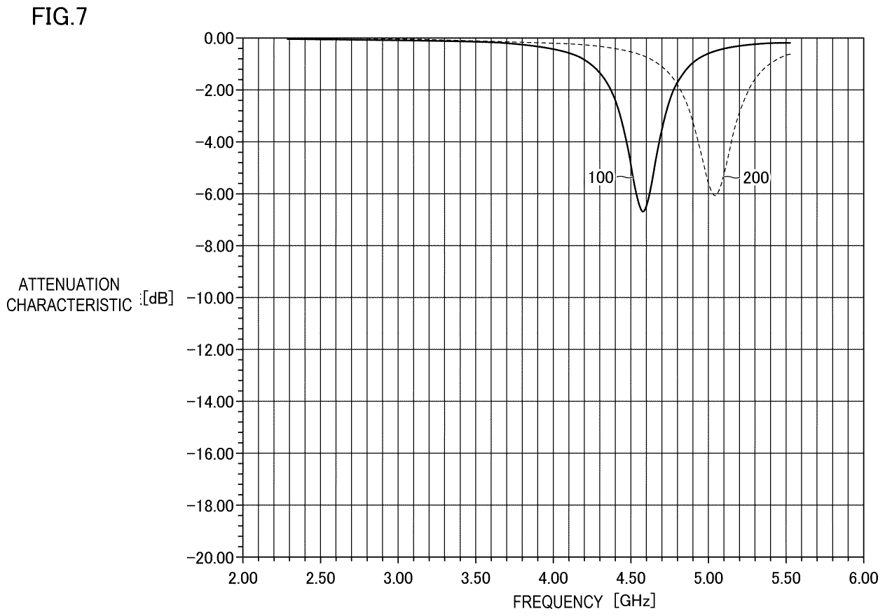

The inductance of the third inductor L3 is smaller in the filter device 200 than in the filter device 100. Thus, in the filter device 200, the resonant frequency f0 is higher than that of the filter device 100. FIG. 7 is a graph illustrating the attenuation characteristic of the filter device 200 according to Embodiment 2. Referring to FIG. 7, the horizontal axis represents the frequency and the vertical axis represents the attenuation characteristic. The attenuation increases downward in FIG. 3. The resonant frequency f0 is about 4.85 GHz in the filter device 100 and about 5.05 GHz in the filter device 200. Accordingly, it can be understood from FIG. 7 that, when the inductance of the third inductor L3 reduces compared to that of the filter device 100, the resonant frequency f0 of the filter device 200 increases. Furthermore, the coupling coefficient k does not vary between the filter device 100 and the filter device 200, and accordingly, the widths of the respective attenuation poles illustrated in FIG. 7 are substantially the same. The resonant frequency f0 of the filter device 200 is reduced compared to the resonant frequency f0 of the filter device without the third inductor L3.

### Embodiment 3

In Embodiment 3, the configuration of a filter device to which a greater inductance than the inductance of the third inductor L3 according to Embodiment 1 is added is described.

### [Structure of Filter Device]

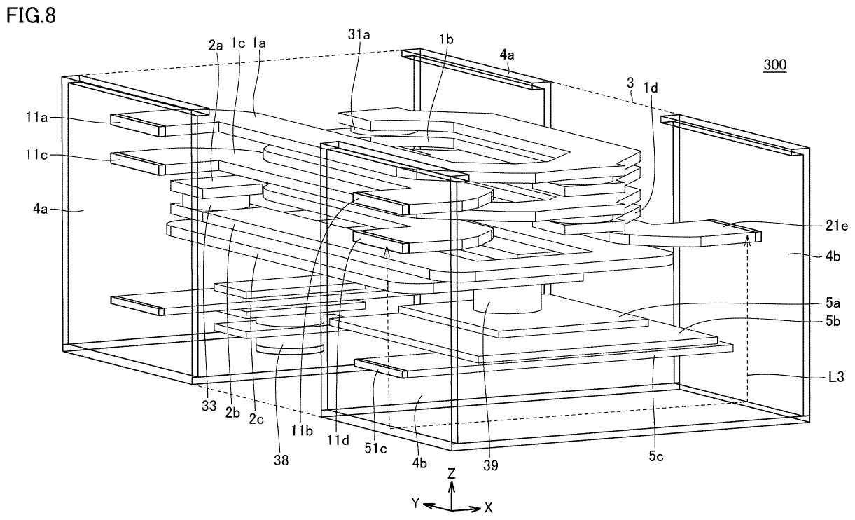

First, a filter device according to Embodiment 3 is described with reference to the drawings. FIG. 8 is a perspective view of a filter device 300 according to Embodiment 3. Here, in FIG. 8, the short edge direction of the filter device 300 is defined as the X direction, the long edge direction of the filter device 300 is defined as the Y direction, and the height direction of the filter device 300 is defined as the Z direction. In the filter device 300 illustrated in FIG. 8, the same elements as those of the filter device 100 illustrated in FIG. 1 are denoted by the same reference numerals, thereby to avoid repetition of the detailed description.

The filter device 300 is a rectangular parallelepiped-shaped chip component in which two inductors and a single capacitor are laminated in the Z direction. The filter device 300 includes the insulating body 3 formed by laminating a plurality of insulating substrates (insulating body layers) on which the first conductor patterns of the first inductor L1, the second conductor patterns of the second inductor L2, and the electrode patterns of the capacitor C1 are formed as illustrated in FIG. 8. Although the configurations of the first inductor L1 and the second inductor L2 of the filter device 300 are the same as those of the filter device 100 illustrated in FIG. 1, the configuration of the capacitor C1 of the filter device 300 is different from that of the filter device 100.

The capacitor C1 is formed by laminating the plurality of electrode patterns 5a to 5c below the second inductor L2 with the insulating layers interposed therebetween. Regarding the capacitor C1, the second conductor pattern 2d (see FIG. 4) of the second inductor L2 and the electrode pattern 5a are electrically connected to each other via the via conductor 37. The electrode pattern 5b is a floating electrode that is not electrically connected to the outer electrode 4b, other wiring patterns, or the like. The electrode pattern 5c is electrically connected to the outer electrode 4b via the wiring pattern 51c at one of the side surfaces (first side surface) of the insulating body 3. The via conductor 41 electrically connected to the outer electrode 4b is not provided in the electrode pattern 5c. That is, the capacitor C1 has neither a path through which the electricity flows from the outer electrode 4b provided on the one of the side surfaces (first side surface) to the outer electrode 4b provided on the other side surface (second side surface) via the electrode pattern 5c and the wiring pattern 51c nor a path through which the electricity flows from the outer electrode 4b provided on one of the side surfaces to the outer electrode 4b provided on the bottom surface via the via conductor 41.

Thus, in the filter device 300, the third inductor L3 includes a path extending from the wiring patterns 11b and 11d provided at a first end of the first inductor L1 through the outer electrode 4b provided on the side surface (first side surface), the outer electrode 4b provided on the bottom surface, and the outer electrode 4b provided on the side surface (second side surface) of the insulating body 3, to the wiring pattern 21e provided at the first end of the second inductor L2. In the third inductor L3, the inductor is formed by a path that passes through the outer electrodes 4b provided in an outer-side portion of the insulating body 3 without passing through an inner-side portion of the insulating body 3. Thus, compared to the case where the inductor is formed by the path passing through the inner side portion of the insulating body 3 illustrated in FIG. 1, the inductance increases. The opening surface of the third inductor L3 illustrated in FIG. 8 is formed in the XZ plane. Thus, the magnetic coupling between the first inductor L1 and the third inductor L3 is weaker than the magnetic coupling between the first inductor L1 and the second inductor L2.

The second inductor L2, the third inductor L3, and the capacitor C1 are connected in series in the insulating body 3 and included in an LC series resonator. Accordingly, the filter device 300 produces an attenuation pole by using the LC series resonator and has a resonant frequency.

### [Exploded Plan View of Filter Device]

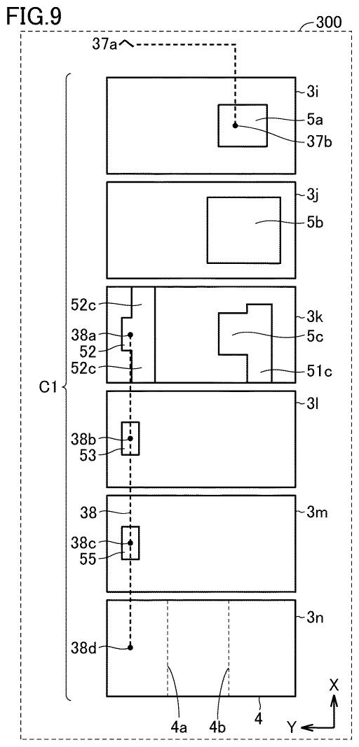

Next, the configuration of each layer is described with reference to an exploded plan view. FIG. 9 is an exploded plan view illustrating the configuration of the filter device 300 according to Embodiment 3. Referring to FIG. 9, the configuration of the filter device 300 is the same as the configuration of the filter device 300 illustrated in FIG. 1 except for that the configuration of the capacitor C1 is different from that of the filter device 100. Thus, exploded plan views of the first inductor L1 and the second inductor L2 are omitted from FIG. 9, and the same elements as those of the filter device 100 are denoted by the same reference numerals, thereby to avoid repetition of the detailed description.

The electrode pattern 5c included in the other electrode of the capacitor C1 is formed on the insulating substrate 3k. In plan view seen from the top surface side, the electrode pattern 5c is provided at a position facing the electrode pattern 5b. The electrode pattern 5c is electrically connected to the outer electrode 4b (see FIG. 8) at one of the side surfaces via the wiring patterns 51c. The electrode pattern 5c is not electrically connected to the outer electrode 4b (see FIG. 8) at the other side surface. As illustrated in FIG. 9, the wiring pattern 51c may also extend toward the outer electrode 4b at the other side surface to which the wiring pattern 51c is not electrically connected. When the extending portion of the wiring pattern 51c is provided, this portion can be utilized as part of the capacitance of the capacitor C1, and variation of the characteristics of the capacitor C1 in the manufacturing can be suppressed. In plan view seen from the top surface side, in the insulating substrate 3k, the wiring pattern 52 is provided at a position on the left side of the insulating body 3. The wiring pattern 52 is electrically connected to the outer electrodes 4a on both the side surfaces facing each other with the wiring patterns 52c interposed therebetween. The wiring pattern 52 includes the connection portion 38a connected to the via conductor 38.

In the capacitor C1, the electrode pattern 5a, the electrode pattern 5b, and the electrode pattern 5c are included in a capacitor. The insulating substrates 31 to 3n are further provided in the lower layer of the capacitor C1. The insulating substrate 31 includes the wiring pattern 53 including the connection portion 38b connected to the via conductor 38. The insulating substrate 3m includes the wiring pattern 55 including the connection portion 38c connected to the via conductor 38. The insulating substrate 3n includes the connection portion 38d connected to the via conductor 38. The via conductor 38 is electrically connected to the outer electrode 4a provided on the bottom surface via the connection portion 38d. The filter device 300 does not include the wiring pattern 54 or 56 or the via conductor 39 or 41 provided in the filter device 100 illustrated in FIG. 1.

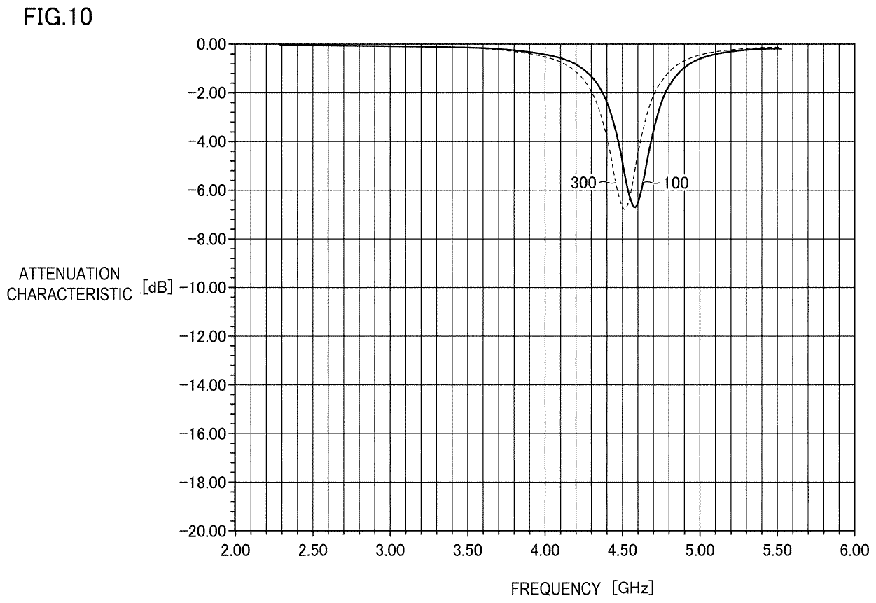

The inductance of the third inductor L3 is greater in the filter device 300 than in the filter device 100. Thus, in the filter device 300, the resonant frequency f0 is lower than that of the filter device 100. FIG. 10 is a graph illustrating the attenuation characteristic of the filter device 300 according to Embodiment 3. Referring to FIG. 10, the horizontal axis represents the frequency and the vertical axis represents the attenuation characteristic. The attenuation increases downward in FIG. 10. The resonant frequency f0 is about 4.85 GHz in the filter device 100 and about 4.50 GHz in the filter device 300. Accordingly, it can be understood from FIG. 10 that, when the inductance of the third inductor L3 increases compared to that of the filter device 100, the resonant frequency f0 of the filter device 300 increases. Furthermore, the coupling coefficient k does not vary between the filter device 100 and the filter device 300, and accordingly, the widths of the respective attenuation poles illustrated in FIG. 10 are substantially the same.

### Modifications

With reference to the circuit diagram of the filter device 100 illustrated in FIG. 2, the second path TL2 is described as the short path. When the inductance of the second path TL2 is reduced so as to be smaller than the mutual inductance M between the first inductor L1 and the second inductor L2, the second path TL2 can be regarded as the short path. Thus, the inductance of the second path TL2 may be smaller than the mutual inductance M between the first inductor L1 and the second inductor L2.

In the above-described embodiments, the magnitude relationship between the inductance of the first inductor L1 and the inductance of the second inductor L2 is not particularly described. However, the inductance of the first inductor L1 may be smaller than the inductance of the second inductor L2. In this way, loss of the entirety of the filter device can be reduced.

In the above-described embodiments, it is described that the first inductor L1 is electrically connected to the outer electrode 4b at the first conductor patterns 1b and 1d and the second inductor L2 is electrically connected to the outer electrode 4b at the second conductor pattern 2a. However, the conductor pattern for the electrical connection to the outer electrode 4b is not limited to the first conductor pattern 1b or 1d or the second conductor pattern 2a but may be another conductor pattern. The inductance of the third inductor L3 can be adjusted by changing the conductor pattern for the electrical connection to the outer electrode 4b. For example, when the first inductor L1 is electrically connected to the outer electrode 4b at the first conductor patterns 1a and 1c disposed outside the first conductor patterns 1b and 1d, the length of the path included in the third inductor L3 increases, and accordingly, the inductance increases.

In the above-described embodiments, the position where the first conductor patterns 1b and 1d and the outer electrode 4b are electrically connected to each other or the position where the second conductor pattern 2a and the outer electrode 4b are electrically connected to each other is not particularly limited. The coupling coefficient k can be changed by moving the connection position in the Y-axis direction. For example, when the connection position is provided near the center of the insulating body 3, the areas of the opening portions of the first inductor L1 and the second inductor L2 reduce. Thus, the coupling coefficient k can be reduced. In contrast, when the connection position is provided near an end portion of the insulating body 3, the areas of the opening portions of the first inductor L1 and the second inductor L2 increase. Thus, the coupling coefficient k can be increased.

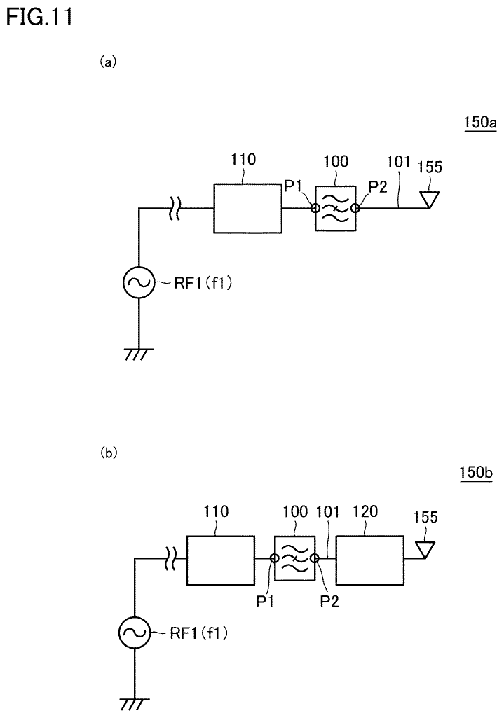

In the above-described embodiments, as illustrated in (b) FIG. 2, the antenna device 150 including the feeding circuit RF1, the filter device 100, and the radiating element 155 is described. However, the antenna device including the filter device 100 is not limited to the antenna device 150 illustrated in (b) of FIG. 2. For example, the antenna device including the filter device 100 may further include a matching circuit. FIG. 11 includes circuit diagrams of an antenna device 150a and an antenna device 150b according to Modification 1. In the antenna device 150a and the antenna device 150b illustrated in FIG. 11, the same elements as those of the antenna device 150 illustrated in FIG. 2 are denoted by the same reference numerals, thereby to avoid repetition of the detailed description.

The antenna device 150a illustrated in (a) of FIG. 11 includes the feeding circuit RF1, the filter device 100, a matching circuit 110, and the radiating element 155. The radiating element 155 and the feeding circuit RF1 are connected to each other via wiring 101. The filter device 100 and the matching circuit 110 are connected in series with the wiring 101. The matching circuit 110 is provided between the feeding circuit RF1 and the filter device 100. The matching circuit 110 is provided for matching the impedance with the radiating element 155, the feeding circuit RF1, the filter device 100, and the like. The matching circuit 110 includes resistance, inductance, capacitance, and the like.

The matching circuit may be provided not only between the feeding circuit RF1 and the filter device 100 but also between the filter device 100 and the radiating element 155. The antenna device 150b illustrated in (b) of FIG. 11 includes the feeding circuit RF1, the filter device 100, matching circuits 110 and 120, and the radiating element 155. The antenna device 150b further includes the matching circuit 120 between the filter device 100 and the radiating element 155. The matching circuit 120 is connected in series with the wiring 101 and provided for matching the impedance with the radiating element 155, the feeding circuit RF1, the filter device 100, and the like. The matching circuit 120 includes resistance, inductance, capacitance, and the like. The matching circuit 120 may have the same configuration as that of the matching circuit 110 or a different configuration from that of the matching circuit 110.

In the antenna device 150b, the matching circuit 110 is provided between the feeding circuit RF1 and the filter device 100 and the matching circuit 120 is provided between the filter device 100 and the radiating element 155. However, the antenna device 150b may include only the matching circuit 120. Furthermore, in the antenna device 150a illustrated in (a) of FIG. 11 and the antenna device 150b illustrated in (b) of FIG. 11, the matching circuits 110 and 120 are connected in series with the wiring 101. However, at least one of the matching circuits 110 and 120 may be connected in parallel (connected in shunt) between the wiring 101 and the ground (GND).

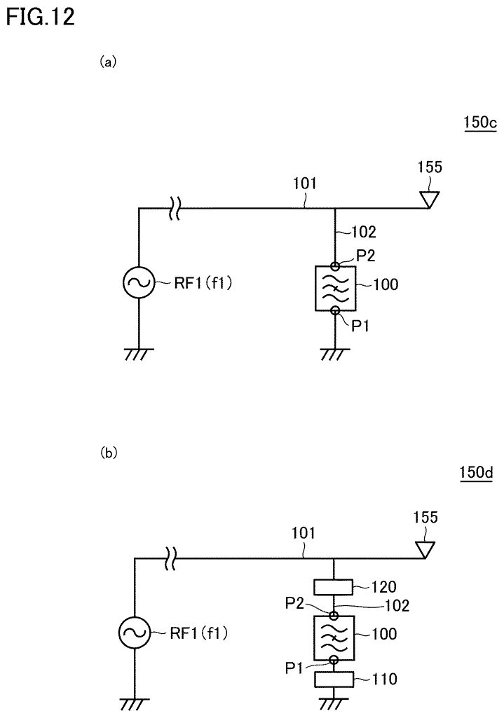

In the above-described embodiment, the antenna device 150 in which, as illustrated in (b) of FIG. 2, the filter device 100 is connected in series with the feeding circuit RF1 and the radiating element 155 is described. However, the antenna device including the filter device 100 is not limited to the antenna device 150 illustrated in (b) of FIG. 2. For example, the antenna device may include the filter device 100 connected in parallel with the feeding circuit RF1. FIG. 12 includes circuit diagrams of an antenna device 150c and an antenna device 150d according to Modification 2. In the antenna device 150c and the antenna device 150d illustrated in FIG. 12, the same elements as those of the antenna device 150 illustrated in FIG. 2 are denoted by the same reference numerals, thereby to avoid repetition of the detailed description.

The antenna device 150c illustrated in (a) FIG. 12 includes the feeding circuit RF1, the filter device 100, and the radiating element 155. The radiating element 155 and the feeding circuit RF1 are connected to each other via the wiring 101. The filter device 100 is connected in parallel between the wiring 101 and the GND. That is, the antenna device 150c includes the filter device 100 in which the terminal P1 (first terminal) is connected to the GND and the terminal P2 (second terminal) is connected to the wiring 101.

Although nothing is connected to wiring 102 to which the filter device 100 is connected in the antenna device 150c, a matching circuit may be connected to the wiring 102. The antenna device 150d illustrated in (b) of FIG. 12 includes the feeding circuit RF1, the filter device 100, the matching circuits 110 and 120, and the radiating element 155. The matching circuits 110 and 120 are connected in series with the wiring 102 to which the filter device 100 is connected in the antenna device 150d. The matching circuit 110 is connected between the GND and the filter device 100, and the matching circuit 120 is connected between the filter device 100 and the wiring 101.

The matching circuits 110 and 120 are provided for matching the impedance with the radiating element 155, the feeding circuit RF1, the filter device 100, and the like. The matching circuits 110 and 120 include resistance, inductance, capacitance, and the like. The matching circuits 110 and 120 may have the same configurations or different configurations.

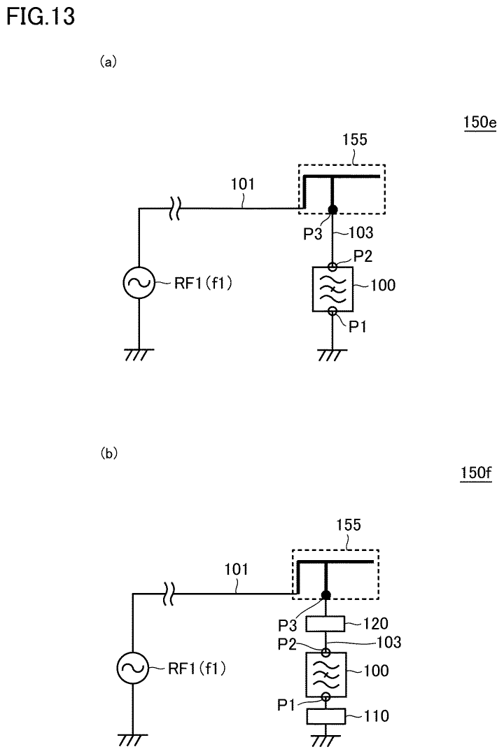

In the above-described embodiment, the antenna device 150 in which, as illustrated in (b) of FIG. 2, the filter device 100 is provided in the wiring 101 connecting the radiating element 155 and the feeding circuit RF1 to each other is described. However, the antenna device including the filter device 100 is not limited to the antenna device 150 illustrated in (b) of FIG. 2. For example, the filter device 100 may be provided at the short point of the radiating element in the antenna device. FIG. 13 includes circuit diagrams of an antenna device 150e and an antenna device 150f according to Modification 3. In the antenna device 150e and the antenna device 150f illustrated in FIG. 13, the same elements as those of the antenna device 150 illustrated in FIG. 2 are denoted by the same reference numerals, thereby to avoid repetition of the detailed description.

The antenna device 150e illustrated in (a) of FIG. 13 includes the feeding circuit RF1, the filter device 100, and the radiating element 155. The radiating element 155 is, for example, an inverted-F antenna having a short point P3. The short point P3 is connected to the GND via wiring 103. The filter device 100 is not provided in the wiring 101 connecting the radiating element 155 and the feeding circuit RF1 to each other but in the wiring 103. That is, the antenna device 150e includes the filter device 100 connected in parallel with the feeding circuit RF1. That is, the antenna device 150e includes the filter device 100 in which the terminal P1 (first terminal) is connected to the GND and the terminal P2 (second terminal) is connected to the short point P3.

Although nothing is connected to the wiring 103 to which the filter device 100 is connected in the antenna device 150e, a matching circuit may be connected to the wiring 103. The antenna device 150f illustrated in (b) of FIG. 13 includes the feeding circuit RF1, the filter device 100, the matching circuits 110 and 120, and the radiating element 155. The matching circuits 110 and 120 are connected in series with the wiring 103 to which the filter device 100 is connected in the antenna device 150f. The matching circuit 110 is connected between the GND and the filter device 100, and the matching circuit 120 is connected between the filter device 100 and the short point P3 of the radiating element 155.

The matching circuits 110 and 120 are provided for matching the impedance with the radiating element 155, the feeding circuit RF1, the filter device 100, and the like. The matching circuits 110 and 120 include resistance, inductance, capacitance, and the like. The matching circuits 110 and 120 may have the same configurations or different configurations.

### EMBODIMENT

(1) A filter device according to the present disclosure has an attenuation band. The filter device includes
a first terminal,
a second terminal,
a first inductor connected to the first terminal, and
a series resonator disposed in a first path out of the first path and a second path provided in parallel with each other between the first inductor and the second terminal.

The series resonator includes
a second inductor,
a capacitor connected in series with the second inductor, and
a third inductor connected in series with the second inductor and the capacitor.

Magnetic coupling between the first inductor and the third inductor is weaker than magnetic coupling between the first inductor and the second inductor.

In this way, when the filter device according to the present disclosure includes the third inductor with a weak magnetic coupling, a steep filter device having an attenuation pole in a low frequency band can be realized.

(2) In the filter device according to (1),
an inductance of the second path is smaller than a mutual inductance between the first inductor and the second inductor.

(3) In the filter device according to (1) or (2),
an inductance of the first inductor is smaller than an inductance obtained by combining the second inductor and the third inductor.

(4) In the filter device according to any one of (1) to (3),
the first inductor, the second inductor, the third inductor, and the capacitor are provided in an insulating body having a pair of main surfaces facing each other and four side surfaces connecting the main surfaces to each other.

The insulating body includes
a first outer electrode included in the first terminal and
at least one second outer electrode included in the second terminal.

The third inductor is provided by utilizing part of the second outer electrode.

(5) In the filter device according to (4),
when seen in plan view from one of the main surfaces side, an opening surface of the third inductor forming a coil is perpendicular to an opening surface of the first inductor forming a coil.

(6) In the filter device according to (4) or (5),
the at least one second outer electrode includes a plurality of second outer electrodes, and the plurality of second outer electrodes are provided at least on a first side surface and a second side surface facing the first side surface.

One end of the first inductor is electrically connected to the second outer electrode provided on the first side surface,
one end of the second inductor is electrically connected to the second outer electrode provided on the second side surface, another end of the second inductor is electrically connected to a first electrode of the capacitor, and
a second electrode of the capacitor faces the first electrode and is electrically connected to the first side surface and the second side surface of the second outer electrodes.

The third inductor includes a path extending from the one end of the first inductor through the second outer electrode on the first side surface, the second electrode of the capacitor, and the second outer electrode on the second side surface to the one end of the second inductor.

(7) In the filter device according to (6),
a single path is included in the third inductor.

(8) In the filter device according to (4) or (5),
the at least one second outer electrode includes a plurality of second outer electrodes, and the plurality of second outer electrodes are provided at least on a first side surface, a second side surface facing the first side surface, and a first main surface being one of the main surfaces.

One end of the first inductor is electrically connected to the second outer electrode provided on the first side surface, and
one end of the second inductor is electrically connected to the second outer electrode provided on the first side surface.

The third inductor includes a path extending from the one end of the first inductor through the second outer electrode on the first side surface to the one end of the second inductor.

(9) In the filter device according to (4) or (5),
the at least one second outer electrode includes a plurality of second outer electrodes, and the plurality of second outer electrodes are provided at least on a first side surface, a second side surface facing the first side surface, and a first main surface being one of the main surfaces.

One end of the first inductor is electrically connected to the second outer electrode provided on the first side surface, and
one end of the second inductor is electrically connected to the second outer electrode provided on the second side surface.

The third inductor includes a path extending from the one end of the first inductor through the second outer electrode on the first side surface, the second outer electrode on the first main surface, and the second outer electrode on the second side surface to the one end of the second inductor.

(10) An antenna device according to the present disclosure is configured to be able to radiate a radio wave. The antenna device includes
a radiating element,
a feeding circuit configured to feed a radio-frequency signal to the radiating element, and
the filter device according to any one of (1) to (9) connected in series between the radiating element and the feeding circuit.

(11) An antenna device according to the present disclosure is configured to be able to radiate a radio wave. The antenna device includes
a radiating element,
a feeding circuit configured to feed a radio-frequency signal to the radiating element, and
the filter device according to any one of (1) to (9) including the first terminal connected to a ground and the second terminal connected to wiring connecting the feeding circuit and the radiating element to each other or connected to a short point of the radiating element.

It is to be understood that the embodiments disclosed herein are exemplary in all respects and are not limiting. It is intended that the scope of the present invention is defined not by the above description but by the claims and includes all changes within meaning and the scope equivalent to the claims.

### REFERENCE SIGNS LIST

1a to 1d first conductor pattern
2a to 2d second conductor pattern
3 insulating body
3a to 3n insulating substrate
4A, 4b outer electrode
5a to 5c electrode pattern
100 to 300 filter device
110, 120 matching circuit
150, 150a to 150f antenna device
155 radiating element
C1 capacitor
L1 first inductor
L2 second inductor
L3 third inductor
RF1 feeding circuit
RS series resonator
TL1 first path
TL2 second path

1. A filter device having an attenuation band, the filter device comprising:
a first terminal;
a second terminal;
a first inductor connected to the first terminal;
a first path and a second path provided in parallel with each other between the first inductor and the second terminal; and
a series resonator in the first path,
wherein the series resonator includes
a second inductor,
a capacitor connected in series with the second inductor, and
a third inductor connected in series with the second inductor and the capacitor, and
wherein magnetic coupling between the first inductor and the third inductor is weaker than magnetic coupling between the first inductor and the second inductor.

2. The filter device according to claim 1,
wherein an inductance of the second path is smaller than a mutual inductance between the first inductor and the second inductor.

3. The filter device according to claim 1,
wherein an inductance of the first inductor is smaller than an inductance obtained by combining the second inductor and the third inductor.

4. The filter device according to claim 1,
wherein the first inductor, the second inductor, the third inductor, and the capacitor are provided in an insulating body having a pair of main surfaces facing each other and four side surfaces connecting the main surfaces to each other,
wherein the insulating body includes
a first outer electrode included in the first terminal, and
at least one second outer electrode included in the second terminal, and
wherein the third inductor is provided by utilizing part of the second outer electrode.

5. The filter device according to claim 4,
wherein, when seen in plan view from one of the main surfaces side, an opening surface of the third inductor forming a coil is perpendicular to an opening surface of the first inductor forming a coil.

6. The filter device according to claim 4,
wherein the at least one second outer electrode includes a plurality of second outer electrodes,
wherein the plurality of second outer electrodes are provided at least on a first side surface and a second side surface facing the first side surface,
wherein a first end of the first inductor is electrically connected to the second outer electrode provided on the first side surface,
wherein a first end of the second inductor is electrically connected to the second outer electrode provided on the second side surface,
wherein a second end of the second inductor is electrically connected to a first electrode of the capacitor,
wherein a second electrode of the capacitor faces the first electrode and is electrically connected to the first side surface and the second side surface of the second outer electrodes, and
wherein the third inductor includes a path extending from the first end of the first inductor through the second outer electrode on the first side surface, the second electrode of the capacitor, and the second outer electrode on the second side surface to the first end of the second inductor.

7. The filter device according to claim 6,
wherein a single path is included in the third inductor.

8. The filter device according to claim 4,
wherein the at least one second outer electrode includes a plurality of second outer electrodes,
wherein the plurality of second outer electrodes are provided at least on a first side surface, a second side surface facing the first side surface, and a first main surface being one of the main surfaces,
wherein a first end of the first inductor is electrically connected to the second outer electrode provided on the first side surface,
wherein a first end of the second inductor is electrically connected to the second outer electrode provided on the first side surface, and
wherein the third inductor includes a path extending from the first end of the first inductor through the second outer electrode on the first side surface to the first end of the second inductor.

9. The filter device according to claim 4,
wherein the at least one second outer electrode includes a plurality of second outer electrodes,
wherein the plurality of second outer electrodes are provided at least on a first side surface, a second side surface facing the first side surface, and a first main surface being one of the main surfaces,
wherein a first end of the first inductor is electrically connected to the second outer electrode provided on the first side surface,
wherein a first end of the second inductor is electrically connected to the second outer electrode provided on the second side surface, and
wherein the third inductor includes a path extending from the first end of the first inductor through the second outer electrode on the first side surface, the second outer electrode on the first main surface, and the second outer electrode on the second side surface to the first end of the second inductor.

10. The filter device according to claim 4, wherein the first inductor and the second inductor each include a plurality of laminated conductor patterns arranged substantially parallel to the pair of main surfaces.

11. The filter device according to claim 10, wherein an opening of the first inductor and an opening of the second inductor are at least partially superposed when viewed in a plan view from a direction perpendicular to the main surfaces.

12. The filter device according to claim 11, wherein, in the plan view, the opening of the first inductor has a non-rectangular polygonal shape and the opening of the second inductor has a rectangular shape.

13. The filter device according to claim 12, wherein the non-rectangular polygonal shape is a hexagonal shape.

14. The filter device according to claim 4, wherein, in a plan view from a direction perpendicular to the main surfaces, the capacitor does not substantially overlap an opening of the first inductor or an opening of the second inductor.

15. The filter device according to claim 1, wherein the second path is a short path having an inductance smaller than a mutual inductance between the first inductor and the second inductor.

16. An antenna device configured to be able to radiate a radio wave, the antenna device comprising:
a radiating element;
a feeding circuit configured to feed a radio-frequency signal to the radiating element; and
the filter device according to claim 1 connected in series between the radiating element and the feeding circuit.

17. The antenna device according to claim 16, further comprising a matching circuit connected in series with the filter device.

18. An antenna device configured to be able to radiate a radio wave, the antenna device comprising:
a radiating element;
a feeding circuit configured to feed a radio-frequency signal to the radiating element; and
the filter device according to claim 1 including the first terminal connected to a ground and the second terminal connected to wiring connecting the feeding circuit and the radiating element to each other or connected to a short point of the radiating element.

19. The antenna device according to claim 18, wherein the radiating element includes an inverted-F antenna having the short point.

20. A method for manufacturing a filter device, the method comprising:
forming a first inductor within a laminated insulating body, the first inductor coupled to a first terminal;
forming a second inductor and a capacitor within the laminated insulating body;
forming a third inductor within the laminated insulating body;
connecting the second inductor, the capacitor, and the third inductor in series to create a series resonator;
arranging the series resonator in a first path and providing a second path in parallel with the first path, wherein the first and second paths are between the first inductor and a second terminal; and
orienting the first inductor, the second inductor, and the third inductor such that a magnetic coupling between the first inductor and the third inductor is weaker than a magnetic coupling between the first inductor and the second inductor.
